(19) United States
(12) Patent Application Publication
(10) Pub. No.: US 2023/0119543 A1
(43) Pub. Date: Apr. 20, 2023

(54) SERVER

(71) Applicants: Inventec (Pudong) Technology Corporation, Shanghai (CN); INVENTEC CORPORATION, Taipei (TW)

(72) Inventors: Ping-Wei PENG, Taipei (TW); Xishan SHEN, Shanghai (CN)

(21) Appl. No.: 17/693,505

(22) Filed: Mar. 14, 2022

(30) Foreign Application Priority Data
Sep. 15, 2021 (CN) 202111078634.5

(51) Int. Cl. H05K 7/20; H05K 7/14

(52) U.S. Cl. CPC H05K 7/20172; H05K 7/20581; H05K 7/1492; H05K 7/1489

(57) ABSTRACT

A server includes a rack, a chassis, and a fan module. The chassis includes a supporting tray, a bracket, and a first electrical connector. The supporting tray is detachably disposed into the rack along an assembling direction substantially perpendicular to a normal direction thereof. The bracket is disposed at an end of the supporting tray. The first electrical connector is disposed on the bracket. The first electrical connector at least has one end movable or detachable with respect to the bracket along a direction substantially perpendicular to the assembling direction. The fan module is detachably disposed in the bracket along the assembling direction. The fan module includes a fan rack, a fan unit, and a second electrical connector. The fan unit is disposed in the fan rack. The second electrical connector is disposed on the fan rack. The second electrical connector is electrically connected to the first electrical connector.

### CROSS-REFERENCE TO RELATED APPLICATIONS

This non-provisional application claims priority under 35 U.S.C. § 119(a) on Patent Application No(s). 202111078634.5 filed in China, P.R.C. on Sep. 15, 2021, the entire contents of which are hereby incorporated by reference.

### BACKGROUND OF THE INVENTION

### Technical Field of the Invention

The present disclosure relates to a server, more particularly to a server including a detachable fan module.

### Description of the Related Art

A Server is typically equipped with a fan for dissipating heat generated by processing components of the server. In specific, there is a slidable chassis disposed in the rack of the server, and the fan is mounted on the bottom plate of the chassis for generating air-flow flowing towards the processing components in the chassis.

However, the chassis needs to be drawn out of the rack and then the cover of the chassis needs to be opened to expose the bottom plate for installing or removing the fan, which is not convenient.

### SUMMARY OF THE INVENTION

The present disclosure provides a server enabling the installation and removal of a fan without drawing out a chassis from a rack of the server.

According to one aspect of the present disclosure, a server includes a rack, a chassis, and at least one fan module. The chassis includes a supporting tray, at least one bracket, and at least one first electrical connector. The supporting tray has a normal direction and is detachably disposed into the rack along an assembling direction substantially perpendicular to the normal direction. The at least one bracket is disposed at an end of the supporting tray. The at least one first electrical connector is disposed on the at least one bracket. The at least one first electrical connector at least has one end movable or deformable with respect to the at least one bracket along a direction substantially perpendicular to the assembling direction. The at least one fan module is detachably disposed in the at least one bracket along the assembling direction. The at least one fan module includes a fan rack, a fan unit, and a second electrical connector. The fan unit is disposed in the fan rack. The second electrical connector is disposed on the fan rack, and the second electrical connector is configured to be electrically connected to the at least one first electrical connector.

According to the server discussed above, through the arrangement of the supporting tray and the brackets discussed above, the insertion and removal of the fan modules can be performed without drawing the chassis out of the rack. Furthermore, the first electrical connector permits a slight misalignment of inserting the second electrical connector of the fan module, thereby helping and making it easier to correctly electrically connect the second electrical connector to the first electrical connector.

### BRIEF DESCRIPTION OF THE DRAWINGS

The present disclosure will become more fully understood from the detailed description given hereinbelow and the accompanying drawings which are given by way of illustration only and thus are not intending to limit the present disclosure and wherein:

FIG. 1 is a rear view of a server according to one embodiment of the present disclosure;

FIG. 2 is a top view of a chassis of the server in FIG. 1;

FIG. 3 is a rear view of the chassis in FIG. 2;

FIG. 4 is a perspective view of the chassis in FIG. 2;

FIG. 5 is a rear view of the chassis in FIG. 2 without fan modules disposed therein;

FIG. 6 is a perspective view of a fan module of the server in FIG. 1; and

FIG. 7 is another perspective view of the fan module in FIG. 6.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

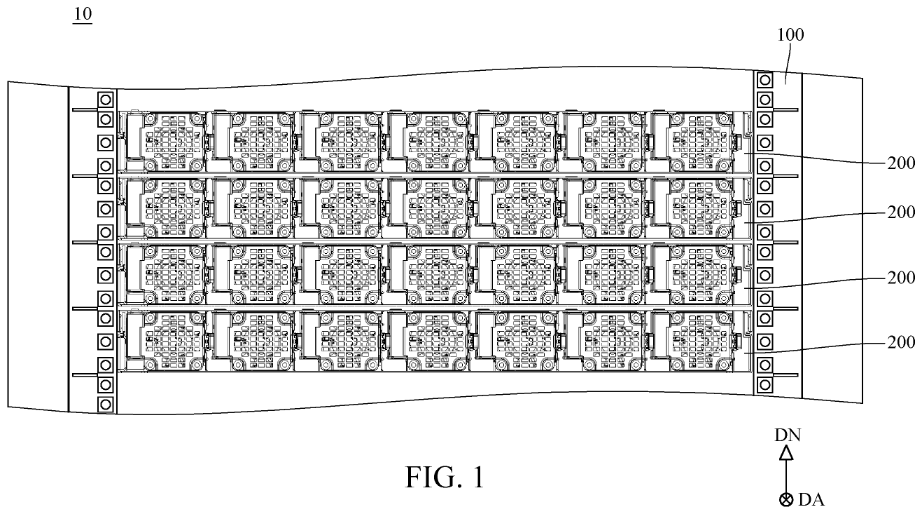

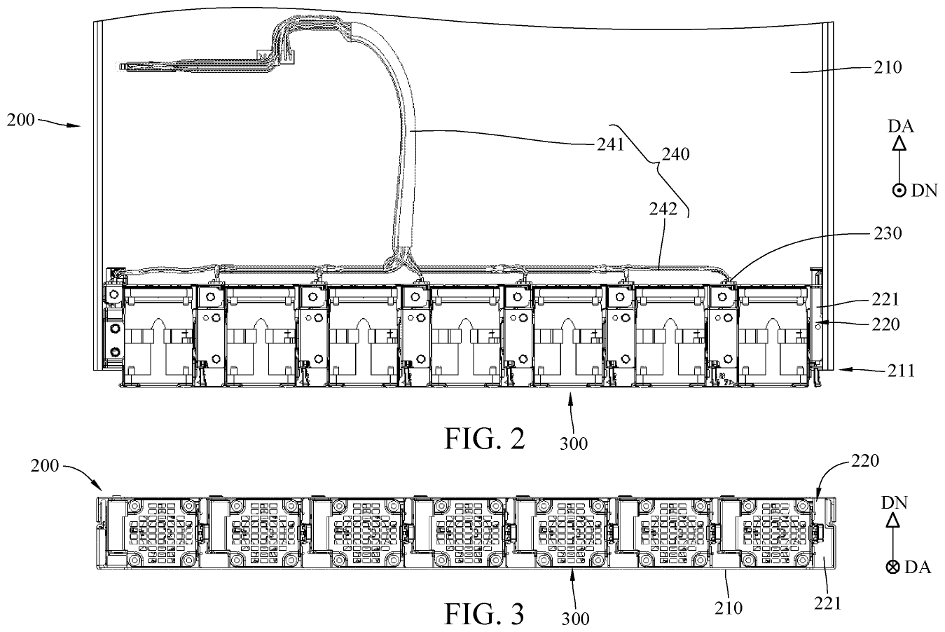

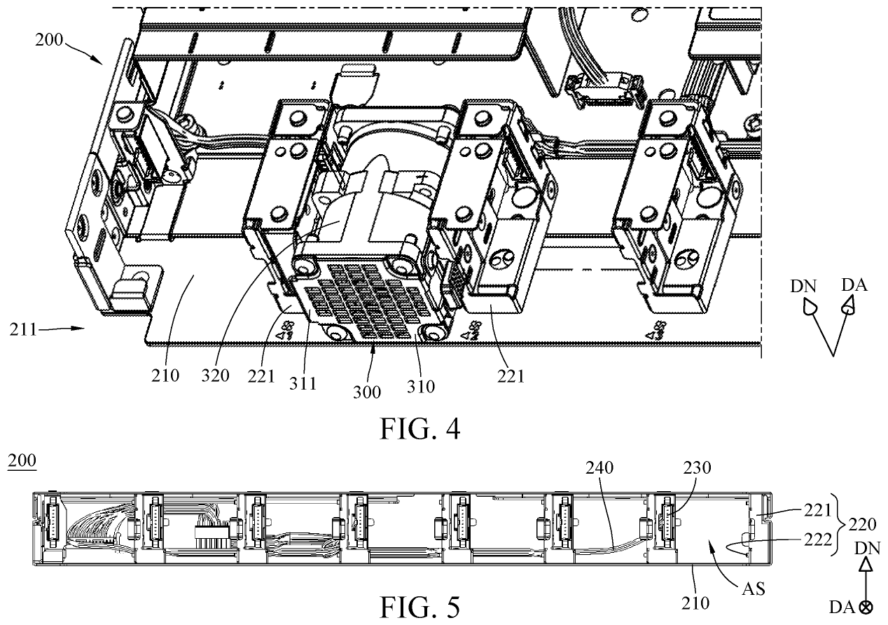

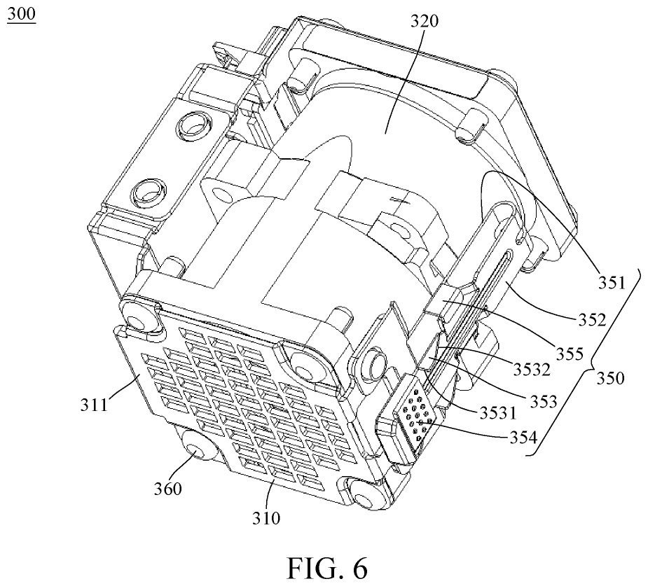

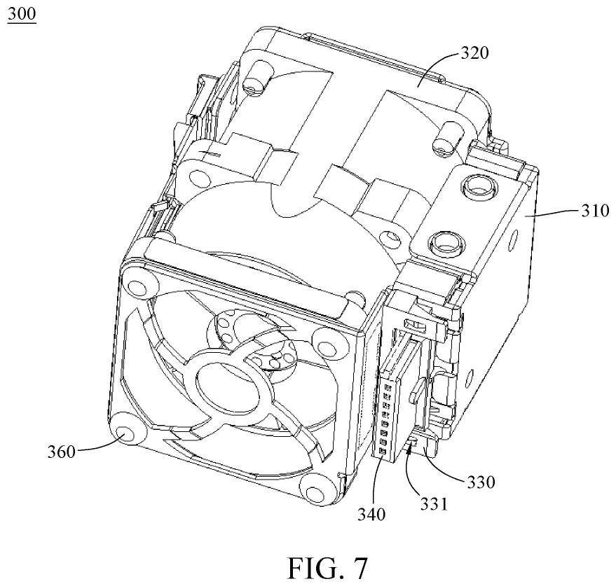

Please refer to FIG. 1 to FIG. 7, where FIG. 1 is a rear view of a server according to one embodiment of the present disclosure, FIG. 2 is a top view of a chassis of the server in FIG. 1, FIG. 3 is a rear view of the chassis in FIG. 2, FIG. 4 is a perspective view of the chassis in FIG. 2, FIG. 5 is a rear view of the chassis in FIG. 2 without fan modules disposed therein, FIG. 6 is a perspective view of a fan module of the server in FIG. 1, and FIG. 7 is another perspective view of the fan module in FIG. 6.

One embodiment of the present disclosure provides a server 10 including a rack 100, a plurality of chassis 200, and a plurality of fan modules 300. The chassis 200 each include a supporting tray 210, a plurality of brackets 220, a plurality of first electrical connectors 230, and an electric connection cable 240.

The supporting tray 210 may be a bottom plate of the chassis 200 and has a normal direction DN. The chassis 200 is detachably disposed in the rack 100 along an assembling direction DA substantially perpendicular to the normal direction DN.

The brackets 220 are disposed at an end 211 of the supporting tray 210, wherein the end 211 may be located close to the rear side of the server 10.

The first electrical connectors 230 are respectively disposed on the brackets 220. Due to the elasticity and flexibility of the material of the first electrical connectors 230, the first electrical connectors 230 may each have one end movable or deformable in a direction substantially perpendicular to the assembling direction DA with respect to the bracket 220 by, for example, approximately 0.15 millimeters when external force is applied thereto.

The electric connection cable 240 includes a main cable part 241 and a plurality branch cable parts 242. The main cable part 241 is disposed on the supporting tray 210 and is electrically connected to the first electrical connectors 230 via the branch cable parts 242, such that the first electrical connectors 230 can be electrically connected to a mainboard (not shown) of the server 10 by plugging the main cable part 241.

The fan modules 300 can be respectively placed into the brackets 220 along the assembling direction DA. The brackets 220 include a plurality of walls 221 and a plurality of bumps 222. Every two adjacent walls 221 form an accommodation space AS therebetween. Each accommodation space AS is configured to accommodate one fan modules 300. The bumps 222 protrude from the walls 221 and located in the accommodation spaces AS. The bumps 222 are configured to contact the fan modules 300 so as to space the fan modules 300 from the walls 221 by a proper gap, such as 0.15 millimeters. This makes the fan modules 300 each have a gap to the walls 221 in a direction substantially perpendicular to the assembling direction DA, such that the contact areas between the fan modules 300 and the walls 221 are significantly reduced to largely reduce the friction therebetween.

In this embodiment, the fan modules 300 each include a fan rack 310, a fan unit 320, a plastic adapter 330, a second electrical connector 340, and an engagement component 350. The fan unit 320 is fixed in the fan rack 310. The plastic adapter 330 is disposed on the fan rack 310. The second electrical connector 340 is fixed to the fan rack 310 via the plastic adapter 330 and is electrically connected to the fan unit 320.

The engagement component 350 includes a first part 351, a second part 352, a plurality of positioners 353, a press part 354, and a plurality of limiting portions 355. The first part 351 and the second part 352 are connected to each other to form a U-shape. The first part 351 is connected to the fan rack 310. The second part 352 is elastically deformable, and the press part 354 is connected to the second part 352. The positioners 353 are located between the second part 352 and the press part 354 and located between the limiting portions 355 and the press part 354. The limiting portions 355 protrude from the first part 351 and are removably engaged with the second part 352. The positioners 353 each have a stopping edge 3531 and a guiding edge 3532 at an angle to the stopping edge 3531. Optionally, there may be a curved edge (not numbered) connected to and located between the stopping edge 3531 and the guiding edge 3532. In addition, the brackets 220 further have protrusions (not shown) at inner sides thereof.

During the insertion of the fan module 300 into the bracket 220, the protrusions at the inner side of the bracket 220 push the guiding edges 3532 of the positioners 353 so as to deform the second part 352, then, as the protrusions move over the curved edges and stopping edges 3531 of the positioners 353, the second part 352 returns to its original position to make the stopping edges 3531 engage with the protrusions of the bracket 220, achieving the engagement between the fan module 300 and the bracket 220. On the other hand, by pushing the press part 354 to release the positioners 353 from the protrusions of the bracket 220, the fan module 300 can be removed from the bracket 220. It is understood that the limiting portions 355 are provide to limit the movable range of the second part 352.

In addition, since one side of each first electrical connector 230 is slightly movable or deformable with respect to the brackets 220, the first electrical connector 230 permits a slight misalignment of inserting the second electrical connector 340 of the fan module 300. This helps and makes it easier to correctly electrically connect the second electrical connector 340 of the fan module 300 to the first electrical connector 230. As the second electrical connector 340 is connected to the first electrical connector 230, the fan module 300 is electrically connected to the mainboard of the server 10 via the branch cable parts 242 and the main cable part 241.

Through the arrangement of the supporting tray 210 and the brackets 220 discussed above, the insertion and removal of the fan modules 300 can be performed without drawing the chassis 200 out of the rack 100. Furthermore, the first electrical connector 230 permits a slight misalignment of inserting the second electrical connector 340 of the fan module 300, thereby helping and making it easier to correctly electrically connect the second electrical connector 340 to the first electrical connector 230.

Optionally, the plastic adapter 330 may have positioning holes 331, and the second electrical connector 340 is disposed on the plastic adapter 330 via the positioning holes 331. Due to the positioning holes 331, the second electrical connector 340 may be movable in a longitudinal direction of the positioning holes 331 substantially perpendicular to the assembling direction DA with respect to the fan rack 310 by, for example, 0.1 millimeters. As such, the second electrical connector 340 can also permit a slight misalignment of inserting the second electrical connector 340 of the fan module 300.

Further, the fan modules 300 may each include plastic fasteners 360 detachably disposed on the fan rack 310 to secure the fan unit 320 to the fan rack 310.

Furthermore, the fan rack 310 may have a protruded part 311 protruded from a side thereof opposite to the engagement component 350 by, for example, 2 millimeters for being easily held by a finger during the removal of the fan module 300.

According to the server discussed above, through the arrangement of the supporting tray and the brackets discussed above, the insertion and removal of the fan modules can be performed without drawing the chassis out of the rack. Furthermore, the first electrical connector permits a slight misalignment of inserting the second electrical connector of the fan module, thereby helping and making it easier to correctly electrically connect the second electrical connector to the first electrical connector.

The embodiments are chosen and described in order to best explain the principles of the present disclosure and its practical applications, to thereby enable others skilled in the art best utilize the present disclosure and various embodiments with various modifications as are suited to the particular use being contemplated. It is intended that the scope of the present disclosure is defined by the following claims and their equivalents.

What is claimed is:

1. A server, comprising:
a rack;
a chassis, comprising:
a supporting tray, having a normal direction, wherein the supporting tray is detachably disposed into the rack along an assembling direction substantially perpendicular to the normal direction;
at least one bracket, disposed at an end of the supporting tray; and
at least one first electrical connector, disposed on the at least one bracket, wherein the at least one first electrical connector at least has one end movable or deformable with respect to the at least one bracket along a direction substantially perpendicular to the assembling direction; and
at least one fan module, detachably disposed in the at least one bracket along the assembling direction, and the at least one fan module comprising:
a fan rack;
a fan unit, disposed in the fan rack; and
a second electrical connector, disposed on the fan rack,
wherein the second electrical connector is configured to be electrically connected to the at least one first electrical connector.

2. The server according to claim 1, wherein the chassis further comprises an electric connection cable, a quantity of the at least one bracket is plural, a quantity of the at least one first electrical connector is plural, the first electrical connectors are respectively disposed on the brackets, the electric connection cable comprises a main cable part and a plurality of branch cable parts, the main cable part is disposed on the supporting tray, and the plurality of branch cable parts are connected to and located between the first electrical connectors and the main cable part.

3. The server according to claim 1, wherein the at least one bracket comprising a plurality of walls and a plurality of bumps, the plurality of walls at least form an accommodation space therebetween for accommodating the at least one fan module, and the plurality of bumps protrude from the plurality of walls and located in the accommodation space.

4. The server according to claim 1, wherein the at least one fan module further comprising an engagement component, the engagement component comprising a first part, a second part, at least one positioner, and a press part, the first part and the second part are connected to each other to form a U-shape, the first part is connected to the fan rack, the second part is connected to the press part, and the at least one positioner is disposed between the second part and the press part; when the at least one fan module is disposed in the at least one bracket, the at least one positioner is engaged with the at least one bracket.

5. The server according to claim 4, wherein the engagement component further comprises at least one limiting portion protruding towards the second part from the first part, and the at least one positioner is located between the at least one limiting portion and the press part.

6. The server according to claim 4, wherein the at least one positioner has a stopping edge, a guiding edge and a curved edge that is connected to and located between the stopping edge and the guiding edge; when the at least one fan module is disposed in the at least one bracket, the stopping edge is engage with the at least one bracket.

7. The server according to claim 1, wherein the at least one fan module further comprises at least one plastic fastener for securing the fan unit to the fan rack.

8. The server according to claim 4, wherein the fan rack has a protruded part at a side thereof opposite to the engagement component.

9. The server according to claim 1, wherein the at least one fan module further comprises a plastic adapter, and the second electrical connector is fixed to the fan rack via the plastic adapter.

10. The server according to claim 9, wherein the plastic adapter has at least one positioning hole, and the second electrical connector is movable along a direction substantially perpendicular to the assembling direction through the at least one positioning hole with respect to the fan rack.
